(19) United States
(12) Patent Application Publication
(10) Pub. No.: US 2026/0353635 A1
(43) Pub. Date: Nov. 5, 2026

(54) SEMICONDUCTOR STRUCTURE AND METHODS OF FORMING THE SAME

(71) Applicant: NANYA TECHNOLOGY CORPORATION, New Taipei City (TW)

(72) Inventor: Jung Tzu PENG, New Taipei City (TW)

(21) Appl. No.: 19/198,120

(22) Filed: May 5, 2025

(51) Int. Cl. H10B 12/00

(52) U.S. Cl. CPC H10B 12/315; H10B 12/033

(57) ABSTRACT

The disclosure provides a semiconductor structure, including a substrate, a landing pad disposed in the substrate, an insulating layer on the substrate and overlying the landing pad, and a capacitor through the insulating layer and connected to the landing pad. The capacitor may be considered as a hybrid capacitor, including a single side capacitor and a double side capacitor on the single side capacitor, which may improve the uniformity between an inner and outer dielectric layer, and further increase the total capacitance of the capacitor.

### BACKGROUND

### Field of Invention

The present invention relates to a semiconductor structure and a method of forming the same. More particularly, the present invention relates to dynamic random-access memory (DRAM).

### Description of Related Art

As the technology of the semiconductor process continuously developed, the dimension of the semiconductor structure shrinks down. In order to achieve the faster computation speed, it is necessary to increase the storage ability of the capacitor.

The double side capacitors have gradually received attention recently. However, the double side capacitors may suffer the uniformity issue between the outer dielectric and the inner dielectric due to the shrinking size of the semiconductor structure.

Therefore, a method of forming a capacitor with uniform dielectrics and larger capacitance in the art is important.

### SUMMARY

The disclosure provides a semiconductor structure, including a substrate, a landing pad disposed in the substrate, an insulating layer on the substrate and overlying the landing pad, and a capacitor through the insulating layer and connected to the landing pad. The capacitor includes a first bottom electrode, a second bottom electrode, a third bottom electrode, a dielectric layer and a top electrode layer. The first bottom electrode is surrounding a sidewall and a bottom surface of the second bottom electrode. The third bottom electrode is connected to the first bottom electrode and extending upwardly. An outer surface of a sidewall of the first bottom electrode and an outer surface of the third bottom electrode extend continuously. The dielectric layer is on a portion of the outer surface of the sidewall of the first bottom electrode and on the second bottom electrode, and surrounding the third bottom electrode. The top electrode layer is disposed on the dielectric layer.

The disclosure provides a method of forming a semiconductor structure, including forming a landing pad in a substrate, forming an insulating layer on the substrate and overlying the landing pad, depositing a sacrificial layer on the substrate and the insulating layer, forming a recess in the sacrificial layer and the insulating layer to expose a top surface of a portion of the landing pad, forming a bottom electrode in a bottom portion of the recess and connected to the landing pad. The bottom electrode includes a first bottom electrode and a second bottom electrode. The first bottom electrode is along a sidewall and a bottom surface of the recess and connected to the landing pad. The second bottom electrode is on the first bottom electrode, wherein a top surface of the first bottom electrode is coplanar with a top surface of the second bottom electrode. The method further includes forming a third bottom electrode along the sidewall of the recess and connected to the first bottom electrode, removing the sacrificial layer, conformally forming a first dielectric layer on the exposed bottom electrode and the third bottom electrode, and surrounding the third bottom electrode and forming a top electrode layer on the first dielectric layer and in the remaining recess.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-9 are cross-sectional views of various formation stages of a method of forming a semiconductor device according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

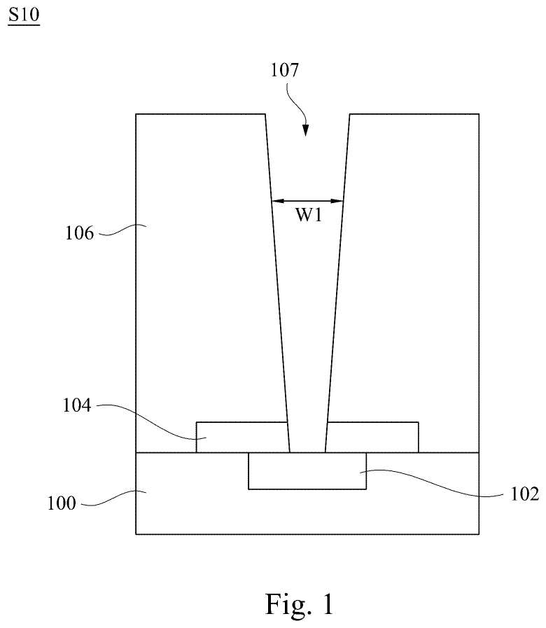

FIGS. 1-9 are cross-sectional views of various formation stages of a method of forming a semiconductor structure according to some embodiments of the present disclosure.

Referring to FIG. 1, the method begins from step S10. Providing a substrate 100. A landing pad 102 is formed in the substrate 100. In some embodiments, a top surface of the landing pad 102 is exposed in top portion of the substrate 100. An insulating layer 104 is on the substrate 100 and overlying the landing pad 102. A sacrificial layer 106 is deposited on the insulating layer 104 and the substrate 100. In some embodiments, a material of the landing pad 102 may include Ti, TiN, Ta, TaN, W, Cu, Au, or alloys thereof. In some embodiments, a material of the insulating layer 104 may be any suitable dielectric material, such as silicon oxide, silicon nitride, silicon oxynitride, tetraethylorthosilicate (TEOS) oxide, or the like. In some embodiments, a material of the sacrificial layers 106 may include dielectric material, such as silicon oxide, silicon nitride, borophosphosilicate glass (BPSG), or the like.

A recess 107 is formed in the sacrificial layer 106 and the insulating layer 104 to expose a portion of a top surface of the landing pad 102. The formation of the recess 107 may be performed by any suitable removing process, such as an anisotropic dry etch process. The recess 107 may have a width W1 in a direction parallel to the substrate 100. The width W1 of the recess 107 may be decreasing gradually towards the substrate 100. In other words, the width W1 of a top portion of the recess 107 may be larger than the width W1 of a bottom portion of the recess 107.

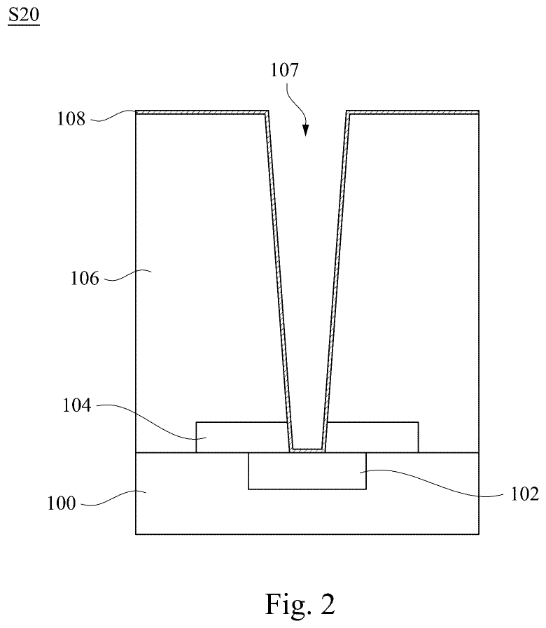

Referring to FIG. 2, the method goes to step S20. A first bottom electrode layer 108 is formed conformally in the recess 107 and on the sacrificial layer 106. In some embodiments, the first bottom electrode layer 108 may be made of metals, metal compounds, alloy compounds, other conductive materials or combinations thereof, such as titanium, titanium nitride or silicon-doped titanium nitride. In some embodiments, the formation of the first bottom electrode layer 108 may be deposited by any suitable deposition process, such as chemical vapor deposition (CVD), physical vapor deposition (PVD), atomic layer deposition (ALD), low-pressure CVD (LPCVD), plasma-enhanced chemical vapor deposition (PECVD), e-beam evaporation, MBE or the like.

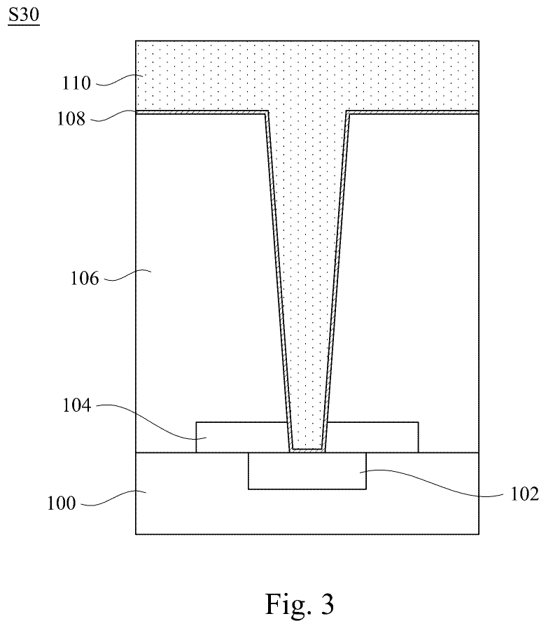

Referring to FIG. 3, the method goes to step S30. A second bottom electrode layer 110 is deposited on the first bottom electrode layer 108 and overfilling the remaining recess 107 (as shown in FIG. 2). In some embodiments, the second bottom electrode layer 110 may be made of metals, metal compounds, alloy compounds, other conductive materials or combinations thereof, such as titanium, tungsten or poly. In some embodiments, the formation of the second bottom electrode layer 110 may be deposited by any suitable deposition process, such as CVD, PVD, ALD, e-beam evaporation, or the like.

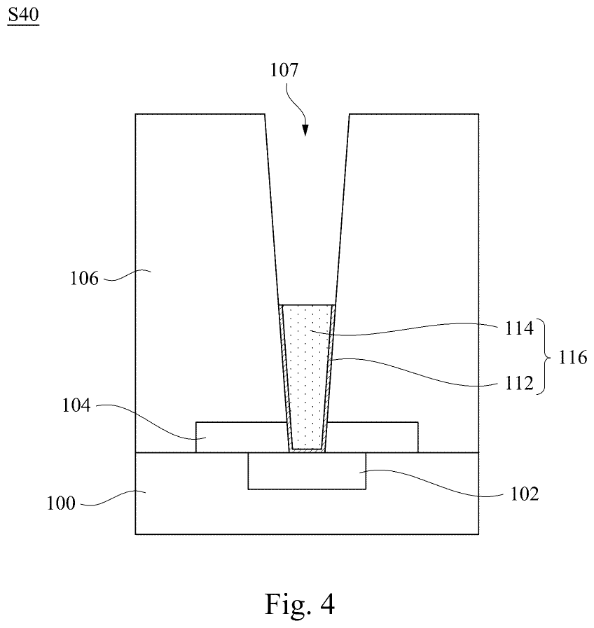

Referring to FIG. 4, the method goes to step S40. A bottom electrode 116 is formed in a bottom portion of the recess 107. Portions of the first bottom electrode layer 108 and the second bottom electrode layer 110 (as shown in FIG. 3) over the sacrificial layer 106 and in a top portion of the recess 107 are removed to form the bottom electrode 116. The bottom electrode 116 includes a first bottom electrode 112 and a second bottom electrode 114 on the first bottom electrode 112. After the removal process, the remaining first bottom electrode layer 108 is referred as the first bottom electrode 112, and the remaining second bottom electrode layer 110 is referred as the second bottom electrode 114. The first bottom electrode 112 is disposed along a sidewall and a bottom surface of the recess 107 and connected to the landing pad 102. A bottom surface and sidewall of the second bottom electrode 114 is surrounded by the first bottom electrode 112. In some embodiments, a top surface of the second bottom electrode 114 is coplanar with a top surface of the first bottom electrode 112. In some embodiments, the removal of the portions of the first bottom electrode layer 108 and the second bottom electrode layer 110 may be performed by any suitable etching process, such as reactive ion etching (RIE), wet etching, plasma etching, inductively coupled plasma (ICP) etching, or the like.

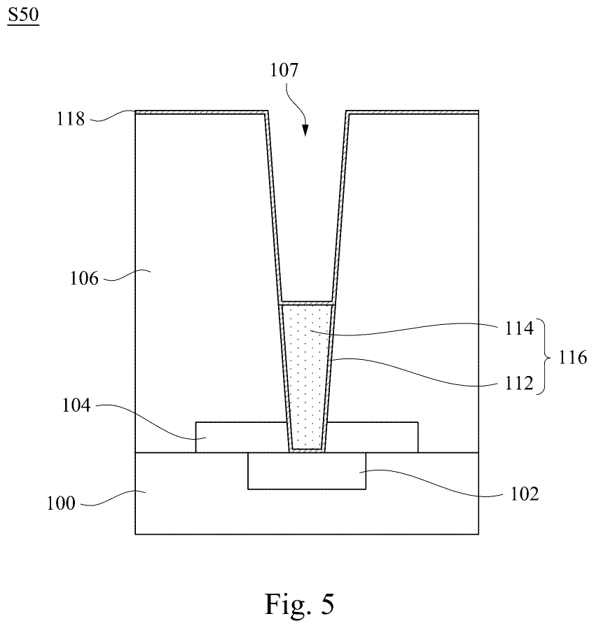

Referring to FIG. 5, the method goes to step S50. A third bottom electrode layer 118 is formed conformally in the remaining recess 107 and on the sacrificial layer 106. In some embodiments, the third bottom electrode layer 118 may be made of metals, metal compounds, alloy compounds, other conductive materials or combinations thereof, such as titanium, titanium nitride or silicon-doped titanium nitride. In some embodiments, a material of the third bottom electrode layer 118 may be the same as a material of the first bottom electrode layer 108. In some embodiments, the formation of the third bottom electrode layer 118 may be performed by any suitable deposition process, such as CVD, PVD, ALD, LPCVD, PECVD, e-beam evaporation, MBE or the like.

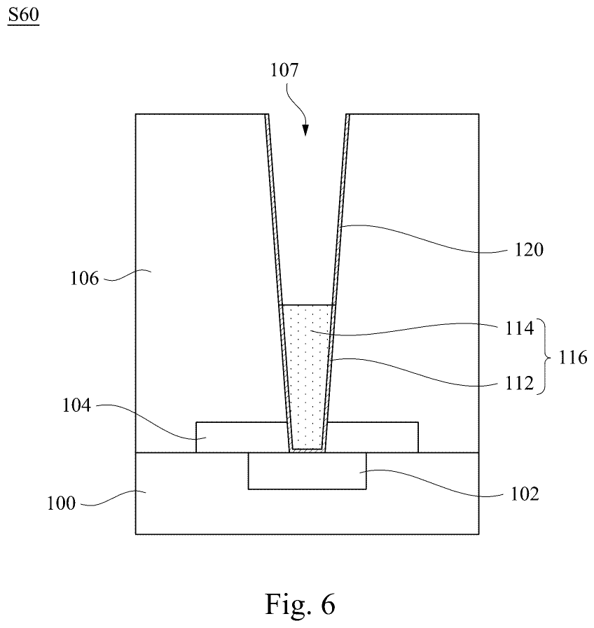

Referring to FIG. 6, the method goes to step S60. A third bottom electrode 120 is formed. A horizontal portion of the third bottom electrode layer 118 (as shown in FIG. 5) on the sacrificial layer 106 and the bottom portion of the remaining recess 107 is removed to expose top surfaces of the sacrificial layer 106 and the second bottom electrode 114. The third bottom electrode 120 may be located on the sidewall of the remaining recess 107 and connected to the first bottom electrode 112. Since the first bottom electrode 112 and the third bottom electrode 120 are formed conformally in the recess 107, an outer surface of a sidewall of the first bottom electrode 112 and an outer surface of the third bottom electrode 120 extend continuously in some embodiments. In some embodiments, a top surface of the third bottom electrode 120 is coplanar with the top surface of the sacrificial layer 106. In some embodiments, the removal of the third bottom electrode 120 may be performed by any suitable process, such as an anisotropic dry etch process.

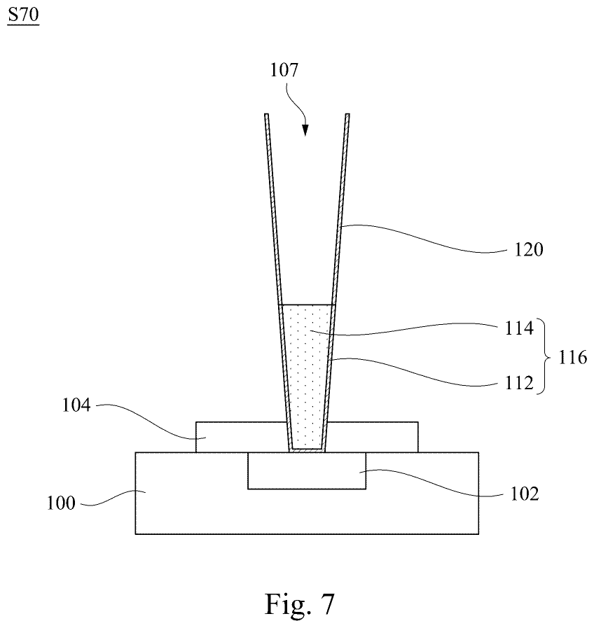

Referring to FIG. 7, the method goes to step S70. The sacrificial layer 106 is removed. After the removal of the sacrificial layer 106, the remaining structure including the bottom electrode 116 and the third bottom electrode 120 is landing on the landing pad 102 through the insulating layer 104 in a direction perpendicular to the substrate 100. The third bottom electrode 120 is connected to the first bottom electrode 112 and extending upwardly. In some embodiments, the removal of the sacrificial layer 106 is performed by any suitable etching process, such as RIE, ICP, wet etching.

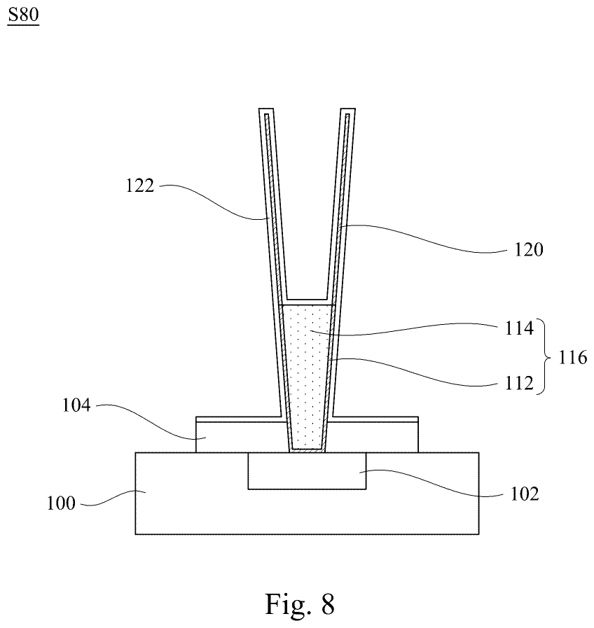

Referring to FIG. 8, the method goes to step S80. A dielectric layer 122 is formed. The dielectric layer 122 is conformally deposited on the exposed bottom electrode 116 and the third bottom electrode 120. Specifically, the dielectric layer 122 is formed on the exposed sidewall of the first bottom electrode 112, on the top surface of the second bottom electrode 114, on the top surface of the insulating layer 104, and surrounding the third bottom electrode 120. The third bottom electrode 120 is wrapped by the dielectric layer 122. On the other hands, an inner surface and the outer surface of the third bottom electrode 120 is adjacent to the dielectric layer 122. In some embodiments, a thickness of the dielectric layer 122 on the outer surface of the dielectric layer 122 and a thickness of the dielectric layer 122 on the inner surface of the dielectric layer 122 may be comparable.

In some embodiments, the dielectric layer 122 may be formed by dielectric layers including HfO₂, HZO, ZrO₂ or the combinations thereof. Each of the dielectric layers may be used in different thickness. In some embodiments, each of the dielectric layers may have a thickness in a range from 0.5 nm to 10 nm. In some embodiments, the formation of the dielectric layer 122 may be performed by any suitable deposition process, such as CVD, PVD, ALD, LPCVD, PECVD, e-beam evaporation, MBE or the like.

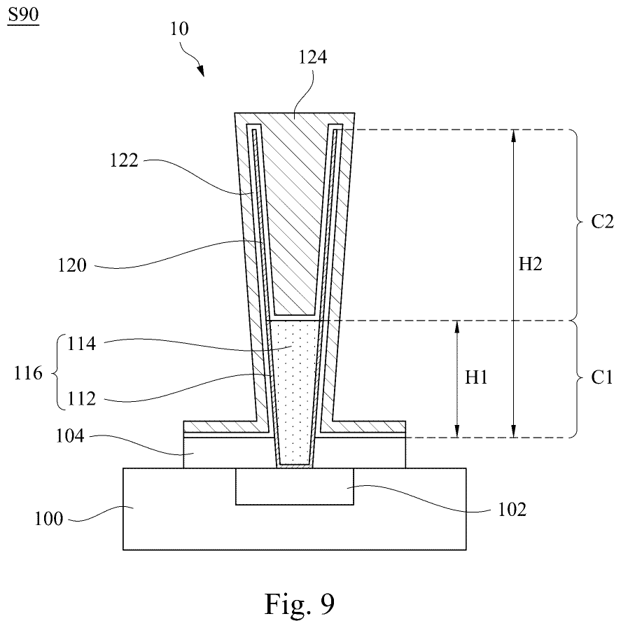

Referring to FIG. 9, the method goes to step S90. A capacitor 10 is formed. A top electrode layer 124 is deposited on the dielectric layer 122 and overfilling the remaining recess 107. In some embodiments, the top electrode layer 124 may be made of metals, metal compounds, alloy compounds, other conductive materials or combinations thereof, such as titanium, tungsten or poly. In some embodiments, the formation of the top electrode layer 124 may be performed by any suitable deposition process, such as CVD, PVD, ALD, e-beam evaporation, or the like.

The capacitor 10 may include the bottom electrode 116, the third bottom electrode 120, the dielectric layer 122 and the top electrode layer 124. The third bottom electrode 120 are connected to the first bottom electrode 112 and extending upwardly, and the outer surface of the sidewall of the first bottom electrode 112 and the outer surface of the third bottom electrode 120 extend continuously. In addition, a portion of the sidewall of the first bottom electrode 112 is adjacent to the second bottom electrode 114 and the dielectric layer 122, and the outer surface and the inner surface of the third bottom electrode 120 is adjacent to the dielectric layer 122. Further, the dielectric layer 122 above the second bottom electrode 114 is between the third bottom electrode 120 and the top electrode layer 124.

The capacitor 10 of the present disclosure may be considered as a hybrid capacitor. The capacitor 10 may have a single side capacitor C1 and a double side capacitor C2 on the single side capacitor C1. The single side capacitor C1 may be at a lower portion of the capacitor 10, and the double side capacitor C2 may be at the higher portion of the capacitor 10. The double side capacitor C2 may have a higher capacitance than the single side capacitor C1.

In the direction parallel the substrate 100, the single side capacitor C1 may include the conductive material (such as the first bottom electrode 112 and the second bottom electrode 114), the dielectric material (such as the dielectric layer 122) and the conductive material (such as the top electrode layer 124) sequentially from inside out, and the double side capacitor C2 may include the conductive material (such as the top electrode layer 124 in the recess 107), the dielectric material (such as the dielectric layer 122 on the inner surface of the third bottom electrode 120), the conductive material (such as the third bottom electrode 120), the dielectric material (such as the dielectric layer 122 on the outer surface of the third bottom electrode 120) and the conductive material (such as the top electrode layer 124 on an outer surface of the dielectric layer 122) sequentially from inside out.

Since the lower single side capacitor C1 is formed by deposited the second bottom electrode 114 filling the recess 107, resulting in a better recess-filling ability. The double side capacitor C2 may provide a higher capacitance than the single side capacitor C1. Such the capacitor 10 which the double capacitor C2 is located on the single side capacitor C1 may make the double capacitor C2 and the single side capacitor C1 in parallel and provide a better capacitance performance.

In addition, a height H1 of the single side capacitor C1 may be controlled. The height H1 may be measured from the top surface of the insulating layer 104 to the top surface of the second bottom electrode 114 in the direction perpendicular to the substrate 100. The height H2 may be measured from the top surface of the insulating layer 104 to the top surface of the third bottom electrode 120 in the direction perpendicular to the substrate 100. In some embodiments, a ratio of the height H1 to the height H2 may be in a range from 30% to 70%. As the result, a top surface of the second bottom electrode 114 may be higher than the top surface of the insulating layer 104.

As the ratio is controlled in the range, a thickness of the dielectric layer 122 on the outer surface of the third bottom electrode 120 and a thickness of the dielectric layer 122 on the inner surface of the third bottom electrode 120 may be fine adjusted to be comparable. The thickness of the dielectric layer 122 on the outer surface of the third bottom electrode 120 is measured from the outer surface of the third bottom electrode 120, and the thickness of the dielectric layer 122 on the inner surface of the third bottom electrode 120 is measured from the inner surface of the third bottom electrode 120. In some embodiments, a difference between the thickness of the dielectric layer 122 on the outer surface of the third bottom electrode 120 and the thickness of the dielectric layer 122 on the inner surface of the third bottom electrode 120 may be in a range from 0.1 nm to 0.2 nm. In some embodiments, the thickness of the dielectric layer 122 may be in a range from about 3 nm to about 10 nm. In some embodiments, a thickness of the third bottom electrode 120 may be in a range from about 3 nm to about 15 nm. In some embodiments, a ratio of a thickness of the third bottom electrode 120 to the thickness of the dielectric layer 122 may be in a range from 1 to 1.5. In such way, a total capacitance of the capacitor 10 calculated by plus a capacitance of the double side capacitor C2 and a capacitance of the single side capacitor C1 may be further increased.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor structure, comprising:
a substrate;
a landing pad disposed in the substrate;
an insulating layer on the substrate and overlying the landing pad; and
a capacitor through the insulating layer and connected to the landing pad, the capacitor comprising:
a first bottom electrode;
a second bottom electrode, wherein the first bottom electrode surrounding a sidewall and a bottom surface of the second bottom electrode;
a third bottom electrode connected to the first bottom electrode and extending upwardly, wherein an outer surface of a sidewall of the first bottom electrode and an outer surface of the third bottom electrode extend continuously;
a dielectric layer on a portion of the outer surface of the sidewall of the first bottom electrode and on the second bottom electrode, and surrounding the third bottom electrode; and
a top electrode layer disposed on the dielectric layer.

2. The semiconductor structure of claim 1, wherein in a direction perpendicular to the substrate, a first height between a top surface of the second bottom electrode and the top surface of the insulating layer, a second height between an top surface of the third bottom electrode and the top surface of the insulating layer, a ratio of the first height to the second height is in a range from 30% to 70%.

3. The semiconductor structure of claim 1, wherein a difference between a thickness of the dielectric layer on the outer surface of the third bottom electrode and a thickness of the dielectric layer on an inner surface of the third bottom electrode is in a range from 0.1 nm to 0.2 nm.

4. The semiconductor structure of claim 1, wherein a material of the dielectric layer comprise HfO₂, HZO, ZrO₂ or combinations thereof.

5. The semiconductor structure of claim 1, wherein a ratio between a thickness of the third bottom electrode to a thickness of the dielectric layer is in a range from 1 to 1.5.

6. The semiconductor structure of claim 5, wherein the thickness of the dielectric layer is measured from an inner surface of the third bottom electrode.

7. The semiconductor structure of claim 1, wherein the dielectric layer above the second bottom electrode is between the third bottom electrode and the top electrode layer.

8. The semiconductor structure of claim 1, wherein a portion of the sidewall of the first bottom electrode is adjacent the second bottom electrode and the dielectric layer.

9. The semiconductor structure of claim 1, wherein a material of the first bottom electrode and a material of the third bottom electrode are the same.

10. The semiconductor structure of claim 1, wherein a top surface of the second bottom electrode is higher than the top surface of the insulating layer.

11. The semiconductor structure of claim 1, wherein the capacitor comprises a single side capacitor and a double side capacitor on the single side capacitor.

12. The semiconductor structure of claim 1, wherein the outer surface and an inner surface of the third bottom electrode is adjacent to the dielectric layer.

13. A method of forming a semiconductor structure, comprising:
forming a landing pad in a substrate;
forming an insulating layer on the substrate and overlying the landing pad;
depositing a sacrificial layer on the substrate and the insulating layer;
forming a recess in the sacrificial layer and the insulating layer to expose a top surface of a portion of the landing pad;
forming a bottom electrode in a bottom portion of the recess and connected to the landing pad, wherein the bottom electrode comprises:
a first bottom electrode along a sidewall and a bottom surface of the recess and connected to the landing pad; and
a second bottom electrode on the first bottom electrode, wherein a top surface of the first bottom electrode is coplanar with a top surface of the second bottom electrode;
forming a third bottom electrode along the sidewall of the recess and connected to the first bottom electrode;
removing the sacrificial layer;
conformally forming a dielectric layer on the exposed bottom electrode and the third bottom electrode; and
forming a top electrode layer on the dielectric layer and in the remaining recess.

14. The method of claim 13, wherein forming the recess in the sacrificial layer and the insulating layer comprises:
etching portions of the insulating layer and the sacrificial layer to form the recess in the sacrificial layer and through the insulating layer, wherein the recess comprises a width in a direction parallel to the substrate, and the width is decreasing towards the substrate.

15. The method of claim 13, wherein forming the bottom electrode comprises:
conformally forming a first bottom electrode layer in the recess and on the sacrificial layer;
depositing a second bottom electrode layer on the first bottom electrode layer and overfilling the recess; and
etching portions of the first bottom electrode layer and the second bottom electrode layer.

16. The method of claim 13, wherein forming the third bottom electrode comprises:
conformally forming a third bottom electrode layer in the remaining recess and on the sacrificial layer; and
removing a horizontal portion of the third bottom electrode layer on the sacrificial layer and the bottom portion of the recess.

17. The method of claim 13, wherein forming the dielectric layer comprises:
depositing the dielectric layer on an exposed sidewall of the first bottom electrode and on the second bottom electrode, and surrounding the third bottom electrode.
